(19) United States
(12) Patent Application Publication
(10) Pub. No.: US 2026/0145255 A1
(43) Pub. Date: May 28, 2026

(54) LIGHT SOLDERING DEVICE

(71) Applicant: SAMSUNG ELECTRONICS CO., LTD., Suwon-si (KR)

(72) Inventors: MINHWAN SEO, Suwon-si (KR); Jungchul Lee, Suwon-si (KR); Taegyu Kang, Suwon-si (KR); Sangwoo Bae, Suwon-si (KR); Myeonghyeon Yu, Suwon-si (KR)

(73) Assignee: SAMSUNG ELECTRONICS CO., LTD., Suwon-si (KR)

(21) Appl. No.: 19/244,209

(22) Filed: Jun. 20, 2025

(30) Foreign Application Priority Data
Nov. 28, 2024 (KR) 10-2024-0174071

(51) Int. Cl. B23K 1/005; B23K 1/00; B23K 3/08; B23K 101/40; H01L 23/00

(52) U.S. Cl. CPC B23K 1/005; B23K 1/0016; B23K 3/08; B23K 2101/40; H10W 72/07141

(57) ABSTRACT

A light soldering device may include: a chamber; a support inside the chamber, the support configured to support an object, the object including a substrate and an electronic component on the substrate; a plurality of light irradiators above the support, inside the chamber, the plurality of light irradiators configured to irradiate light to the object on the support; and a reflective member on the plurality of light irradiators inside the chamber, the reflective member configured to reflect the light from the plurality of light irradiators toward the object, wherein at least one of the plurality of light irradiators comprises a first region that is configured to emit less light than other light irradiators from among the plurality of light irradiators.

### CROSS-REFERENCE TO RELATED APPLICATION

This application claims priority to and the benefit of Korean Patent Application No. 10-2024-0174071, filed at the Korean Intellectual Property Office on Nov. 28, 2024, the disclosure of which is incorporated herein by reference in its entirety.

### BACKGROUND

### 1. Field

Some embodiments of the present disclosure relate to a light soldering device.

### 2. Description of Background Art

In the semiconductor industry, light soldering technology may be used for soldering electronic components on a substrate using intense pulsed light (IPL). Light soldering technology may rapidly increase the temperature of the soldering material, and has advantages such as lower power consumption, shorter process time, and reduced maintenance costs compared to soldering technology using convection heat transfer.

To improve the temperature deviation in different regions of the object being irradiated during light soldering, it is important to control light uniformity.

### SUMMARY

According to an embodiment of the present disclosure, a light soldering device capable of improving light uniformity may be provided.

According to an embodiment of the present disclosure, a light soldering device may include: a chamber; a support inside the chamber, the support configured to support an object, the object including a substrate and an electronic component on the substrate; a plurality of light irradiators above the support, inside the chamber, the plurality of light irradiators configured to irradiate light to the object on the support; and a reflective member on the plurality of light irradiators inside the chamber, the reflective member configured to reflect the light from the plurality of light irradiators toward the object, wherein at least one of the plurality of light irradiators comprises a first region that is configured to emit less light than other light irradiators from among the plurality of light irradiators.

According to an embodiment of the present disclosure, a light soldering device may include: a chamber; a support inside the chamber, the support configured to support an object, the object including a substrate and an electronic component on the substrate; at least one light irradiator above the support inside the chamber, the at least one light irradiator extending in a first direction and configured to irradiate light to the object on the support; a first reflective member on the at least one light irradiator inside the chamber, the first reflective member configured to reflect the light from the at least one light irradiator toward the object; and at least one second reflective member on an inner surface of the first reflective member, the inner surface facing towards the support inside the chamber, and the at least one second reflective member is configured to reflect the light from the at least one light irradiator towards opposite sides of the object in the first direction.

According to an embodiment of the present disclosure, a light soldering device may include: a chamber; a support inside the chamber, the support configured to support an object, the object including a substrate and an electronic component on the substrate; a plurality of light irradiators extending in a first direction and spaced apart from each other in a second direction intersecting the first direction, the plurality of light irradiators being above the support inside the chamber, and configured to irradiate light to the object on the support; a first reflective member on the plurality of light irradiators inside the chamber, the first reflective member configured to reflect the light from the plurality of light irradiators toward the object; and a plurality of second reflective members on an inner surface of the first reflective member, the plurality of second reflective members facing towards the support inside the chamber, and the plurality of second reflective members configured to reflect the light from the plurality of light irradiators towards opposite sides of the object in the first direction, wherein the plurality of light irradiators includes a first light irradiator, a second light irradiator, and a third light irradiator sequentially arranged in the second direction, wherein each of the first light irradiator and the third light irradiator includes a first region that is configured to emit less light than the second light irradiator, and wherein each of the plurality of second reflective members includes at least one second-first reflective member between the first light irradiator and the second light irradiator and at least one second-second reflective member between the second light irradiator and the third light irradiator.

### BRIEF DESCRIPTION OF DRAWINGS

FIG. 1 is a perspective view showing a layout of a support, a light irradiator, and a reflective member of a light soldering device according to an embodiment.

FIGS. 2 and 3 are cross-sectional views of a light soldering device according to an embodiment.

FIG. 4 shows the a collection position upon introduction of a second reflective member according to an embodiment of the present disclosure.

FIG. 5 shows a light irradiator according to an embodiment of the present disclosure.

FIGS. 6 and 7 show light irradiators and reflective members according to an embodiment of the present disclosure.

FIG. 8 is an enlarged view of a second reflective member according to an embodiment of the present disclosure.

FIGS. 9A-D show light distributions in a length of a first region in the light irradiator.

FIGS. 10A-F show light distributions according to a gap between the light irradiator and the second reflective member.

FIGS. 11 and 12 are cross-sectional views of a light soldering device according to a comparative example.

FIG. 13 shows a light distribution in the light soldering device according to comparative examples and examples.

FIG. 14 shows a light uniformity in an X direction in the light soldering device according to comparative examples and examples.

FIG. 15 shows a light uniformity in a Y direction in the light soldering device according to comparative examples and examples.

FIG. 16 is a perspective view of a light irradiator according to an embodiment of the present disclosure.

FIG. 17 is a perspective view of a light irradiator according to an embodiment of the present disclosure.

### DETAILED DESCRIPTION

Non-limiting example embodiments of the present disclosure will be described in detail hereinafter with reference to the accompanying drawings, in which example embodiments of the present disclosure are shown. As those skilled in the art would realize, the described embodiments may be modified in various different ways, all without departing from the spirit or scope of the present disclosure.

The drawings and description are to be regarded as illustrative in nature and not restrictive, and like reference numerals designate like elements throughout the specification.

Further, since sizes and thicknesses of components shown in the accompanying drawings may be arbitrarily given to facilitate understanding and ease of description, the present disclosure is not limited to the illustrated sizes and thicknesses. In the drawings, the thicknesses of layers and regions may be exaggerated for clarity. In the drawings, to facilitate understanding and ease of description, the thicknesses of some layers and regions may be exaggerated.

Throughout the specification, the term “connected” may mean not only “directly connected,” but also “indirectly connected” with another element in between. From a similar perspective, this includes being “physically connected,” as well as being “electrically connected.”

It should be understood that when an element such as a layer, film, region, or substrate is referred to as being “on” another element, it may be directly on the other element or intervening elements may also be present. In contrast, when an element is referred to as being “directly on” another element, there are no intervening elements present. Further, being “above” a reference element means being above or below the reference element, and it may not necessarily mean being positioned “above” it in a direction opposite to gravity.

In addition, unless explicitly stated to the contrary, the word “comprise” (or “include”) and variations such as “comprises” (or “includes”) and “comprising” (or “including”) should be understood to imply the inclusion of stated elements but not the exclusion of any other elements.

In addition, the phrase “on a plane” means a view from a position above the object (e.g., from the top), and the phrase “in a cross-section” means a view of a cross-section of the object which is vertically cut from the side.

In addition, throughout the specification, although the terms “first,” “second,” and the like are used to explain various components, the components are not limited to such terms but are only used to distinguish one component from another component. Accordingly, a configuration referred to as the first component in a certain part of the specification may also be referred to as the second component in other parts of the specification.

As used herein, singular forms are intended to include plural forms unless the context clearly indicates otherwise.

Hereinafter, a light soldering device according to example embodiments of the present disclosure and a comparative example will be described with reference to the drawings.

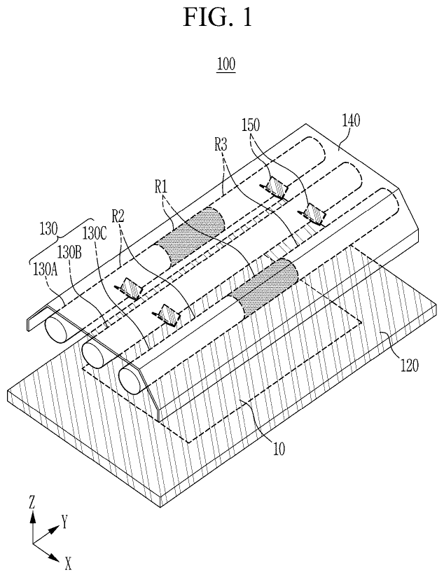

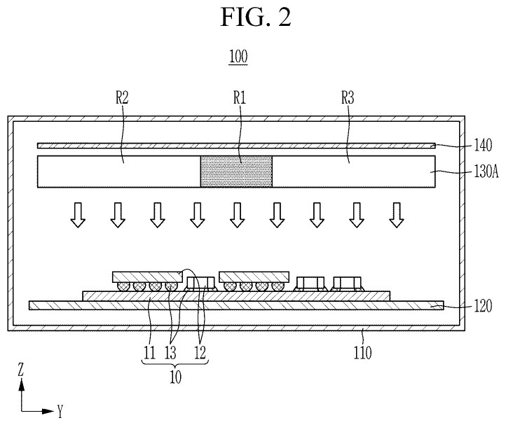

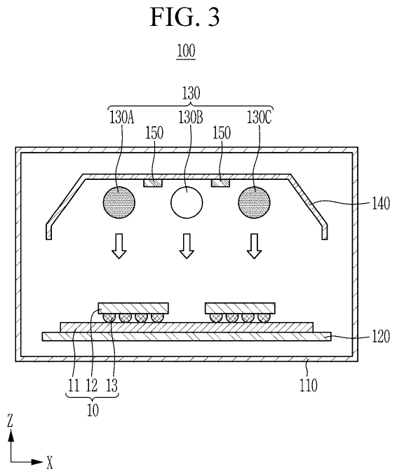

First, referring to FIGS. 1 to 3, a light soldering device 100 according to an embodiment may include a chamber 110, a support 120 on which an object 10 may be mounted, a light irradiator 130, a first reflective member 140, and a second reflective member 150.

The chamber 110 is omitted in FIG. 1, and the object 10 disposed on the support 120 is represented by a dotted line only showing the position where the object 10 is disposed.

The object 10 requiring light soldering may be placed inside the chamber 110. Considering the soldering temperature, the chamber 110 may be formed of a material having excellent heat resistance.

The object 10 may include a substrate 11, an electronic component 12, and a soldering material 13 disposed between the substrate 11 and the electronic component 12. The light soldering device 100 may solder the electronic component 12 on the substrate 11 by irradiating light to the object 10 to melt the soldering material 13.

The support 120 may be disposed inside the chamber 110, and the object 10 may be mounted on the support 120. For example, the object 10 may be introduced into the chamber 110, with the support 120, while mounted on the support 120, or the object 10 may be mounted on the support 120 while the support 120 is in the chamber 110. The number of objects 10 mounted on the support 120 is not particularly limited, and a plurality of objects 10 may be mounted on a single support 120. The number of supports 120 is also not particularly limited, and a plurality of supports 120 may be placed inside the chamber 110.

The light irradiator 130 may be disposed on the support 120 inside the chamber 110 and may irradiate light to the object 10. The light irradiator 130 may irradiate, for example, intense pulsed light (IPL) to the object 10 (e.g., a target object). The IPL may solder the electronic component 12 on the substrate 11 using high-intensity pulsed light. The light irradiator 130 may irradiate light having a wavelength in the range of, for example, 125 nm to 2000 nm or 350 nm to 1200 nm to the object 10 (e.g., the target object). The light irradiator 130 may include a light source such as a lamp—for example, a xenon flash lamp filled with xenon gas inside. The light irradiator 130 may be connected to a power supply device for supplying power.

The light irradiator 130 may extend in the Y direction so that its length in the Y direction may be longer than its length in the X direction. The light irradiator 130 may have, for example, a cylindrical shape extending approximately in the Y direction, but is not limited thereto.

A plurality of light irradiators 130 may be provided. The plurality of light irradiators 130 may be spaced apart from each other in the X direction. For example, the light irradiators 130 may include a first light irradiator 130A, a second light irradiator 130B, and a third light irradiator 130C sequentially arranged in the X direction.

At least one of the light irradiators 130 may include a first region R1 that emits less light than the other light irradiators 130. In this specification, the term ‘emits less light’ is intended to encompass cases where (1) the amount of light emitted per unit area is relatively low in all directions, and (2) the amount of light emitted per unit area is relatively low in a specific direction (e.g., toward the object 10). Accordingly, the first region R1, which emits less light, is capable of irradiating the object 10 with a relatively small amount of light. For example, the first light irradiator 130A and the third light irradiator 130C, which may be positioned at the outermost sides in the X direction, among the light irradiators 130, and may be adjacent to the bent region of the first reflective member 140, may include the first region R1 that emits less light than the second light irradiator 130B. According to an embodiment of the present disclosure, it is possible to emit relatively less light by introducing the first region R1 to the light irradiator 130 positioned in a region where light is concentrated, thereby improving the light uniformity of the light soldering device 100.

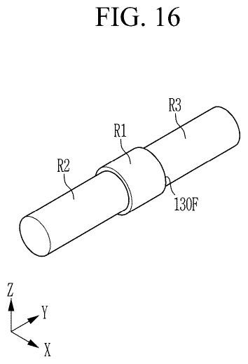

In an embodiment, the first region R1 of the light irradiator 130 may include a light filter 130F (see FIG. 16). The light filter 130F may be, for example, a coating layer of a light source (e.g., a lamp), and may control the transmittance, absorption, reflectance, etc., of light emitted from the light source of the light irradiator 130 to reduce the amount of light emitted from the light irradiator 130.

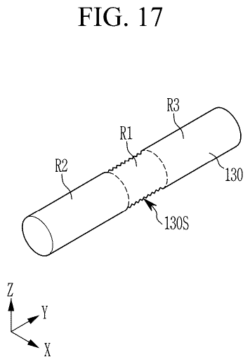

In another embodiment, the first region R1 of the light irradiator 130 may include a light scattering surface 130S (see FIG. 17). The light scattering surface 130S may scatter light emitted from a light source of the light irradiator 130 such that, for example, the scattered light is dispersed rather than concentrated in a specific region.

The light filter 130F and the light scattering surface 130S are example means introduced to reduce the amount of light, and the first region R1 of the light irradiator 130 may also be configured to emit a small amount of light through other means.

The first light irradiator 130A and the third light irradiator 130C including the first region R1 may further include a second region R2 and a third region R3 respectively disposed on both sides of the first region R1 in the Y direction. The first region R1 of the first light irradiator 130A and the third light irradiator 130C may emit less light than the second region R2 and the third region R3. For example, the second region R2 and the third region R3 of each of the first light irradiator 130A and the third light irradiator 130C may emit the same amount of light as the second light irradiator 130B, but they are not limited thereto.

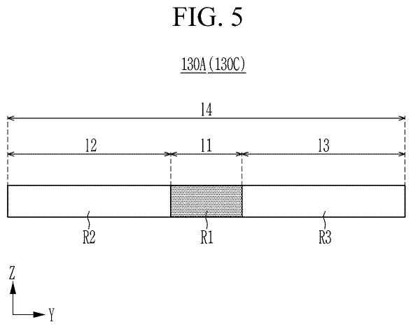

Referring to FIG. 5, a length l1 of the first region R1 of the first light irradiator 130A and the third light irradiator 130C in the Y direction may be 10% or more and 30% or less—for example, 20%—of a length l4 of the light irradiator 130 in the Y direction (Y). The length l1 in the Y direction of the first region R1 of the first light irradiator 130A and the third light irradiator 130C may be about 100 mm.

A length l2 of the second region R2 and a length l3 of the third region R3 in the Y direction of the first light irradiator 130A and the third light irradiator 130C may be substantially the same. As used herein, the term “substantially the same” is not limited to exact identity, but also includes acceptable deviations from a reference value or dimension. For example, “substantially the same” may refer to cases where the difference is within ±10% of a reference value or dimension, provided that such deviation does not significantly affect the intended function, structure, or performance of the components. By making the length l2 of the second region R2 and the length l3 of the third region R3 of the first light irradiator 130A and the third light irradiator 130C the same, light from the light irradiator 130 may be evenly irradiated to both sides of the object 10 in the Y direction.

The first reflective member 140 may be disposed on the light irradiators 130 inside the chamber 110 and may reflect light from the light irradiators 130 toward the object 10.

Both sides of the first reflective member 140 in the X direction may be bent toward the support 120. The bent region of the first reflective member 140 may have a shape that blocks at least one side of the light irradiator 130. For example, the bent region of the first reflective member 140 may block (e.g., surround) one side of each of the outermost light irradiators (e.g., the first light irradiator 130A and the third light irradiator 130C) among the light irradiators 130. The bent region of the first reflective member 140 may block (e.g., surround) the upper and side portions of the light irradiator 130 together with the region disposed on the light irradiator 130 to focus light from the light irradiator 130 on the object 10.

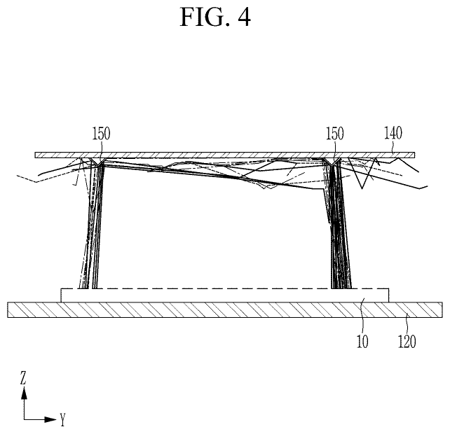

The second reflective member 150 may be disposed on an inner surface of the first reflective member 140 that faces towards the support 120 inside the chamber 110, and may reflect light from the light irradiator 130 toward both sides in the Y direction of the object 10. Referring to the simulation results of FIG. 4, it can be seen that light may be concentrated on both sides in the Y direction of the object 10 mounted on the support 120 via the second reflective member 150.

A plurality of second reflective members 150 may be provided and spaced apart from each other in the X direction with the second light irradiator 130B interposed therebetween. When the plurality of light irradiators 130 are provided, a plurality of second reflective members 150 may each be disposed between the light irradiators 130. For example, a second reflective member 150 may be positioned between the first light irradiator 130A and the second light irradiator 130B and another second reflective member 150 may be positioned between the second light irradiator 130B and the third light irradiator 130C.

Additionally, the plurality of second reflective members 150 may be spaced apart in the Y direction. For example, some of the second reflective members 150 may be spaced apart from each other in the Y direction between the first light irradiator 130A and the second light irradiator 130B, and others of the second reflective members 150 may be spaced apart from each other in the Y direction between the second light irradiator 130B and the third light irradiator 130C.

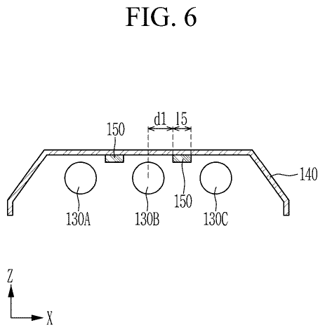

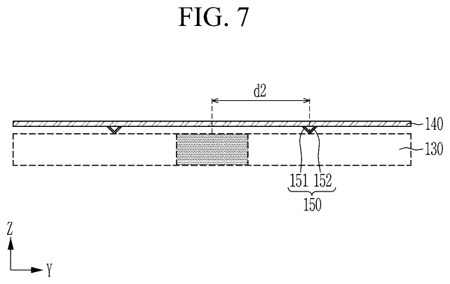

Referring to FIGS. 6 and 7, a minimum distance d1 between the center of the second reflective member 150 and the center of the adjacent light irradiator 130 on the X-Z cross-section may be about 20 mm. Additionally, a length l5 of the second reflective member 150 in the X direction may be about 30 mm. Additionally, a distance d2 between the center of the second reflective member 150 and the center of the light irradiator 130 adjacent thereto on the Y-Z cross-section may be about 140 mm.

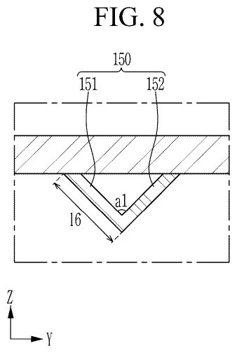

In an embodiment, the second reflective member 150 may have an approximately V-shape in a Y-Z cross-section thereof. For example, the second reflective member 150 may include a first surface 151 and a second surface 152 that are adjacent to each other in the Y direction and are inclined with respect to the first reflective member 140, and a corner formed by the first surface 151 and the second surface 152 may protrude toward the support 120. Referring to FIG. 8, an angle a1 formed by the first surface 151 and the second surface 152 may be 70° or more and 130° or less—for example, about 100°. A minimum length l6 from a point adjacent to the first reflective member 140 of the first surface 151 (or the second surface 152) to a point adjacent to the second surface 152 (or the first surface 151) may be about 15 mm.

On the other hand, in the light soldering device, light from the light irradiator may be concentrated on a specific region of the object.

For example, the amount of light may be concentrated on both sides of the object in the X direction due to the shape, position, and the first reflective member 140 of the light irradiator. According to an embodiment of the present disclosure, by introducing the first region R1 including the light filter, the light scattering surface, etc., the light irradiators (e.g., the first light irradiator 130A and the third light irradiator 130C) positioned in regions where light is concentrated emit relatively low light, thereby improving light uniformity in the X direction.

As another example, when the length of the light irradiator in the Y direction is short in the light soldering device, the amount of light irradiated to both sides of the object in the Y direction may be less than the amount of light irradiated to the center. In this case, a method of increasing the length of the light irradiator to increase the amount of light irradiated to both sides of the object may be considered, but there may be a limit to increasing the length of the light irradiator due to the structure of the equipment. According to an embodiment of the present disclosure, it is possible to concentrate light in the Y direction through the second reflective member, thereby improving light uniformity in the Y direction.

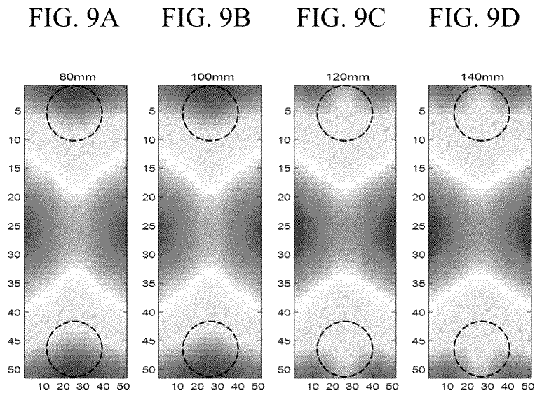

FIGS. 9A-D show light distribution in a length of the first region of the light irradiator.

FIGS. 9A-D) show the light distribution irradiated to an object from the first region R1 of the light irradiator 130 when the length l1 in the Y direction of the first region R1 of the light irradiator 130 is 80 mm, 100 mm, 120 mm, and 140 mm, respectively. The x-axis of FIGS. 9A-D corresponds to the X-direction of the object, and the y-axis corresponds to the Y-direction of the object. Referring to the simulation results, it can be seen that as the length l1 of the first region R1 of the light irradiator 130 in the Y direction becomes longer, the light from the first region R1 of the light irradiator 130 spreads out in the Y direction (see the dotted line region). That is, it can be seen that the light distribution in the X direction may be controlled by introducing the first region R1 of the light irradiator 130, and at the same time, the light distribution in the Y direction may be controlled by adjusting the length of the first region R1.

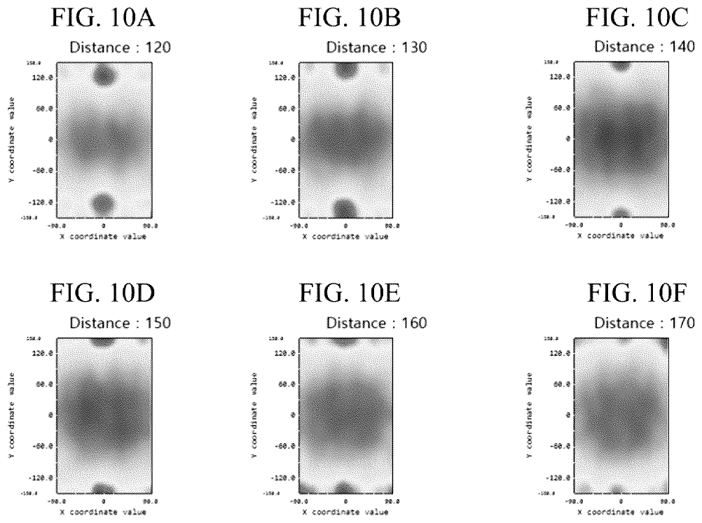

FIGS. 10A-F show light distributions according to the gap between the light irradiator and the second reflective member.

FIGS. 10A-F show the light distribution irradiated from the second reflective member 150 to the object when the distance d2 between the center of the second reflective member 150 and the center of the light irradiator 130 adjacent thereto on the Y-Z cross-section is 120 mm, 130 mm, 140 mm, 150 mm, 160 mm, and 170 mm, respectively. Referring to the simulation results, it can be seen that the position where the amount of light is concentrated in the Y direction may be controlled by adjusting the distance d2 between the center of the second reflective member 150 and the center of the light irradiator 130 adjacent thereto on the Y-Z cross section.

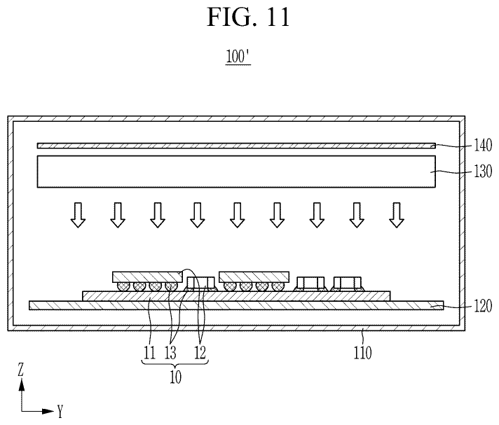

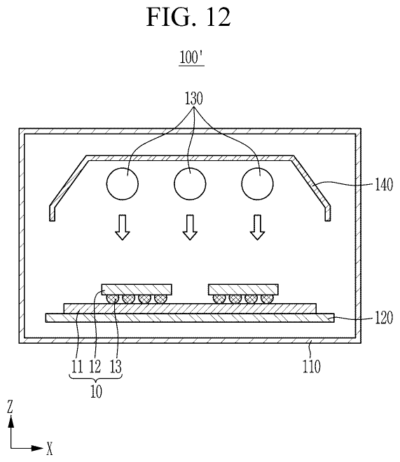

FIGS. 11 and 12 are cross-sectional views of a light soldering device according to a comparative example.

Referring to FIGS. 11 and 12, a light soldering device 100′ according to the comparative example includes the chamber 110, the support 120 on which the object 10 is mounted, the light irradiator 130, and the first reflective member 140, and does not include the second reflective member 150. In addition, the light irradiator 130 of the light soldering device 100′ according to the comparative example emits the same amount of light as the second region R2 and the third region R3 of the light irradiator 130 of the light soldering device 100 without any distinction by region.

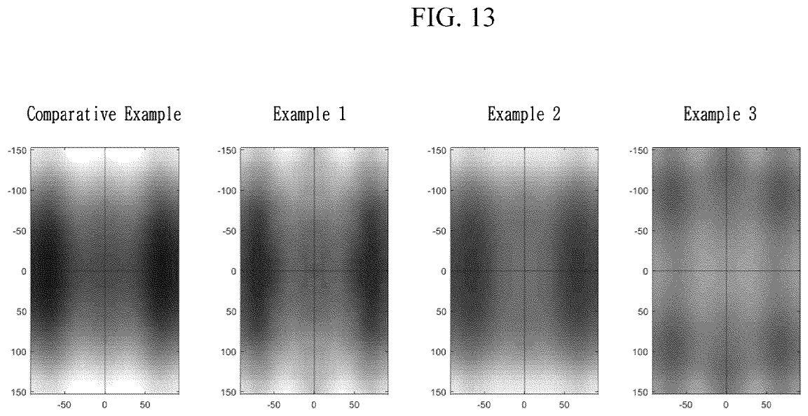

FIG. 13 shows a light distribution in a light soldering device according to comparative examples and examples.

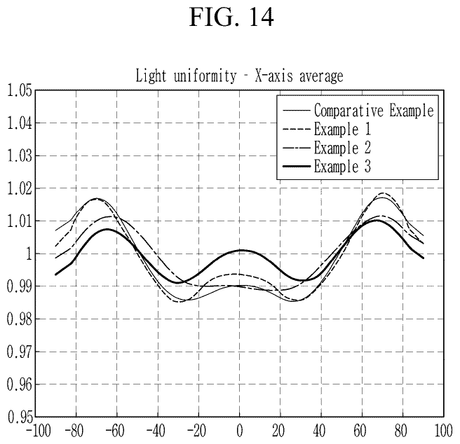

FIG. 14 shows a light uniformity in the X direction in the light soldering device according to comparative examples and examples.

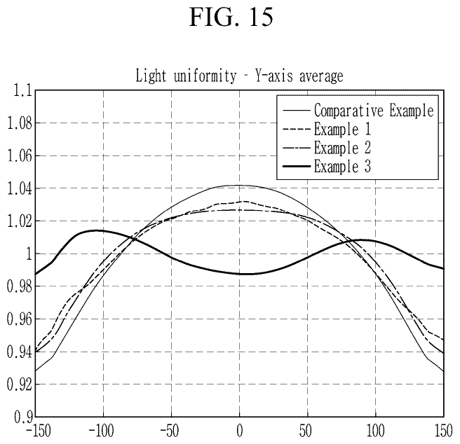

FIG. 15 shows a light uniformity in the Y direction in the light soldering device according to comparative examples and examples.

In FIG. 13, the x-axis corresponds to the X direction of the object, and the y-axis corresponds to the Y direction of the object. Additionally, in FIGS. 14 and 15, each of the y-axes represents the average light uniformity normalized by the accumulated light amount in the X direction and the Y direction (Y).

The light soldering device of Example 3 is the light soldering device 100 according to an embodiment illustrated in FIG. 1. In Example 3, a partial reflection filter with a reflectivity of 40% and a transmittance of 60% was used in the first region R1 of the light irradiator 130, and the length l1 of the first region R1 was 100 mm. In Example 3, the minimum distance d1 between the centers of the second reflective member 150 and the light irradiator 130 adjacent thereto was set to 20 mm, the length l5 of the second reflective member 150 in the X direction was set to 30 mm, the distance d2 between the center of the second reflective member 150 and the center of the light irradiator 130 adjacent thereto was set to 140 mm, and the angle a1 formed by the first surface 151 and the second surface 152 of the second reflective member 150 was set to 100°.

Compared to Example 3, the light soldering device of Example 1 does not include the second reflective member 150.

Compared to Example 3, in the light soldering device of Example 2, an entirety of the first light irradiator 130A and the third light irradiator 130C emit the same amount of light as the second region R2 and the third region R3 of the light irradiator 130 of Example 3, without any distinction by region.

Referring to FIG. 13, the light soldering device 100′ according to the comparative example represents a large amount of light on both sides in the X direction and at the center in the Y direction, and represents a particularly small amount of light on both sides in the Y direction. In the comparative example, the light uniformity was measured at 84.8%. Additionally, the light soldering device according to the examples represents a more uniform light distribution than that of the comparative example. In Examples 1, 2, and 3, the light uniformity was measured as 91.5%, 87%, and 93.9%, respectively.

From the light uniformity graphs of FIGS. 14 and 15, it can also be seen that the examples provide higher light uniformity in the X direction and Y direction than the comparative examples.

While example embodiments of the present disclosure have been described in detail with reference to the accompanying drawings, it is to be understood that the present disclosure is not limited to these example embodiments. On the contrary, various modifications and equivalent arrangements are included within the spirit and scope of the present disclosure.

In addition, the embodiments of the present disclosure are not independent of each other and may be implemented in combination with each other unless they are particularly contradictory. Accordingly, combinations of the embodiments of the present disclosure should also be considered as being included in the present disclosure.

What is claimed is:

1. A light soldering device, comprising:
a chamber;
a support inside the chamber, the support configured to support an object, the object including a substrate and an electronic component on the substrate;
a plurality of light irradiators above the support, inside the chamber, the plurality of light irradiators configured to irradiate light to the object on the support; and
a reflective member on the plurality of light irradiators inside the chamber, the reflective member configured to reflect the light from the plurality of light irradiators toward the object,
wherein at least one of the plurality of light irradiators comprises a first region that is configured to emit less light than other light irradiators from among the plurality of light irradiators.

2. The light soldering device of claim 1, wherein
each of the plurality of light irradiators extends in a first direction, and the plurality of light irradiators are spaced apart from each other in a second direction intersecting the first direction.

3. The light soldering device of claim 2, wherein
the plurality of light irradiators comprises a first light irradiator, a second light irradiator, and a third light irradiator sequentially arranged in the second direction, and
the first light irradiator and the third light irradiator include the first region.

4. The light soldering device of claim 3, wherein
opposite sides of the reflective member in the second direction are bent toward the support.

5. The light soldering device of claim 2, wherein
the at least one of the plurality of light irradiators comprises the first region further comprises a second region and a third region on respective sides of the first region in the first direction, respectively, and
the first region is configured to emit less light than each of the second region and the third region.

6. The light soldering device of claim 5, wherein
a length of the second region in the first direction and a length of the third region in the first direction are substantially the same.

7. The light soldering device of claim 1, wherein
the first region comprises a light filter.

8. The light soldering device of claim 1, wherein
the first region comprises a light scattering surface.

9. The light soldering device of claim 6, wherein
the length of the first region in the first direction is 10% or more and 30% or less of the length of the at least one of the plurality of light irradiators, which comprises the first region, in the first direction.

10. A light soldering device, comprising:
a chamber;
a support inside the chamber, the support configured to support an object, the object comprising a substrate and an electronic component on the substrate;
at least one light irradiator above the support inside the chamber, the at least one light irradiator extending in a first direction and configured to irradiate light to the object on the support;
a first reflective member on the at least one light irradiator inside the chamber, the first reflective member configured to reflect the light from the at least one light irradiator toward the object; and
at least one second reflective member on an inner surface of the first reflective member, the inner surface facing towards the support inside the chamber, and the at least one second reflective member is configured to reflect the light from the at least one light irradiator towards opposite sides of the object in the first direction.

11. The light soldering device of claim 10, wherein
the at least one second reflective member comprises a plurality of second reflective members spaced apart in the first direction.

12. The light soldering device of claim 10, wherein
the at least one second reflective member comprises a plurality of second reflective members spaced apart in a second direction intersecting the first direction with the at least one light irradiator interposed between the plurality of second reflective members.

13. The light soldering device of claim 10, wherein
the at least one light irradiator comprises a plurality of light irradiators spaced apart in a second direction intersecting the first direction, and
the at least one second reflective member comprises a plurality of second reflective members between the plurality of light irradiators.

14. The light soldering device of claim 10, wherein
the at least one second reflective member comprises a first surface and a second surface that are adjacent to each other in the first direction and are inclined with respect to the first reflective member, and
a corner is formed by the first surface and the second surface, and the corner protrudes toward the support.

15. The light soldering device of claim 14, wherein
an angle formed by the first surface and the second surface is 70° or more and 130° or less.

16. A light soldering device, comprising:
a chamber;
a support inside the chamber, the support configured to support an object, the object comprising a substrate and an electronic component on the substrate;
a plurality of light irradiators extending in a first direction and spaced apart from each other in a second direction intersecting the first direction, the plurality of light irradiators being above the support inside the chamber, and configured to irradiate light to the object on the support;
a first reflective member on the plurality of light irradiators inside the chamber, the first reflective member configured to reflect the light from the plurality of light irradiators toward the object; and
a plurality of second reflective members on an inner surface of the first reflective member, the plurality of second reflective members facing towards the support inside the chamber, and the plurality of second reflective members configured to reflect the light from the plurality of light irradiators towards opposite sides of the object in the first direction,
wherein the plurality of light irradiators comprises a first light irradiator, a second light irradiator, and a third light irradiator sequentially arranged in the second direction,
wherein each of the first light irradiator and the third light irradiator comprises a first region that is configured to emit less light than the second light irradiator, and
wherein each of the plurality of second reflective members comprises at least one second-first reflective member between the first light irradiator and the second light irradiator and at least one second-second reflective member between the second light irradiator and the third light irradiator.

17. The light soldering device of claim 16, wherein
the first light irradiator and the third light irradiator further comprise a second region and a third region respectively on opposite sides of the first region in the first direction, and
the first region is configured to emit less light than each of the second region and the third region.

18. The light soldering device of claim 16, wherein
opposite sides of the first reflective member in the second direction are bent toward the support.

19. The light soldering device of claim 16, wherein
the at least one second-first reflective member comprises a plurality of second-first reflective members spaced apart from each other in the first direction, and
the at least one second-second reflective member comprises a plurality of second-second reflective members spaced apart from each other in the first direction.

20. The light soldering device of claim 16, wherein
the plurality of light irradiators are configured to irradiate intense pulsed light to the object.
